(19) United States
(12) Patent Application Publication
(10) Pub. No.: US 2025/0103076 A1
(43) Pub. Date: Mar. 27, 2025

(54) CLOCK TO ANALOG REFERENCE VOLTAGE GENERATOR

(71) Applicant: NVIDIA Corp., Santa Clara, CA (US)

(72) Inventors: Siddharth Saxena, San Jose, CA (US); Sudhir Shrikantha Kudva, Dublin, CA (US); Miguel Rodriguez, Golden, CO (US); Vijay Srinivasan, San Francisco, CA (US); Tezaswi Raja, San Jose, CA (US); Tom Gray, Apex, NC (US); Santosh Santosh, Los Gatos, CA (US)

(73) Assignee: NVIDIA Corp., Santa Clara, CA (US)

(21) Appl. No.: 18/894,507

(22) Filed: Sep. 24, 2024

Related U.S. Application Data
(60) Provisional application No. 63/585,052, filed on Sep. 25, 2023.

(51) Int. Cl. G05F 1/56; G04F 10/00; H03M 7/16

(52) U.S. Cl. CPC G05F 1/56; G04F 10/005; H03M 7/165

(57) ABSTRACT

Reference voltage generators including a header circuit configured to pass current from a power supply to a time-to-digital converter, an amount of the current to pass determined by a thermometer code, and logic to update the thermometer code based on a comparison between an output of the time-to-digital converter and a digital code representing a reference voltage level.

### CROSS-REFERENCE TO RELATED APPLICATIONS

This application claims priority and benefit under 35 U.S.C. 119 (e) to U.S. application Ser. No. 63/585,052, filed on Sep. 25, 2023, the contents of which are incorporated herein by reference in their entirety.

### BACKGROUND

Modern computer processor cores may operate in a wide range of power states spanning, for example, a high performance state (P0) to an ultra-low power IDLE state with data retention (C1). Each state may operate at different supply voltage level, with higher performance states drawing more overall power. Low-dropout voltage regulator (LDO) circuits may be utilized to regulate power from a global domain to the local power domains of different processor cores.

Distributed LDOs driving a shared power delivery network scale with increasing core size to meet the current demands induced by transient loads. However, the minimum dropout achieved by such designs at peak currents is a limiting factor on the maximum achievable operating frequency of the highest-performance power states.

Dropout increases in these designs due to device (e.g., PFET) headers between the global and local power domains being arranged either (1) in rows with a ‘wide’ separation, e.g., by >800 μm, or (2) in a mesh-like network with a substantially lower separation, e.g., a few 100 μm between the PFET clusters. In these layouts, the inherent resistance of the PDN (R_{PDN}) becomes a bottleneck and merely increasing the size of the PFETs does not alleviate the dropout.

One conventional approach utilizes top and bottom rows of PFETs with thick package layers to minimize R_{PDN}. This topology is however not scalable as the cores size increases with increasing current demands. Current is funneled in and out of the top and bottom PFET rows and may rapidly reach the max current limits of vias and bumps.

In the lowest power states, a processor core may be clock-gated and operates at a relatively low voltage (compared to higher power states) that is at least sufficient to retain state. Regulator controller power consumption overhead in these low-power states may negate any leakage power savings achieved with conventional LDO mechanisms.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts a power delivery system in one embodiment.

FIG. 2 depicts the generation of a reference voltage level to the regulators of the power delivery system in one embodiment.

FIG. 3A depicts an embodiment of a power delivery system in other aspects.

FIG. 3B depicts a simplified operating configuration of the regulators in voltage regulated modes in one embodiment.

FIG. 3C depicts a simplified operating configuration of the regulators and retention circuits in retention modes in one embodiment.

FIG. 4A depicts a voltage regulator in accordance with one embodiment.

FIG. 4B depicts example signal behavior for a voltage regulator.

FIG. 5 depicts a comparator circuit in accordance with one embodiment.

FIG. 6 depicts an embodiment of a reference voltage generator at a high level.

FIG. 7 depicts a header circuit for a reference voltage generator in accordance with one embodiment.

FIG. 8 depicts a time-to-digital converter in accordance with one embodiment.

FIG. 9A and FIG. 9B depict thermometer code logic utilized in a feedback loop in accordance with one embodiment.

### DETAILED DESCRIPTION

Disclosed herein are embodiments of power delivery mechanisms comprising (1) finely-distributed power gates to reduce IR dropout in the highest-performance (e.g., P0) state(s), (2) a distributed linear regulator with low area overhead, and (3) a diode-based retention mode for the lowest-power (e.g., C1) state(s). In one embodiment the disclosed mechanisms are utilized in integrated circuits configured to operate in a number of power modes: high performance mode P0 (highest power consumption), regulation modes P1→Pn, and data retention mode C1 (lowest power consumption).

Of the three power modes, the disclosed mechanisms enable the lowest IR drop due to the power regulation to occur in P0 mode, and the retention mode exhibits the lowest overhead power consumption. The regulator may take up lower circuit area than in conventional solutions. The disclosed solutions may be implemented without additional or special power supplies for generating reference voltage levels.

The disclosed power delivery mechanisms may further comprise (1) a special-purpose comparator configured to rapidly respond to load transients, and (2) a metastability tolerant Delay Locking Loop (DLL)-based digital-to-analog converter (DAC) to locally (at each distributed regulator cluster) generate an analog reference voltage from a globally transmitted digital code (VREF_DIG) based on a fixed-frequency clock signal.

To reduce IR dropout in the higher/highest power state(s), power gates may be distributed at a finer (relative to conventional approaches) pitch, for example at a few (e.g., between 10 and 20) micrometers in both X and Y dimensions around the logic layout, and power gate may be disposed in proximity with the logic they control the flow of current to.

Current passing through the power gates may be shorted to the powered logic by way of lower-level metal layers in the chip/die (thinner, more resistive) as well as upper-level metals. The lower-level (closer to the integrated circuit logic) metal layers are thinner and more resistive than the upper-level (closer to the power-supplying metals) layers. Because load current has a short path to travel to any logic cell from the nearest power gate, it predominantly travels in lower-level metals.

In power states other than the highest performance one(s), it may be challenging to implement voltage regulation by way of the power gates on lower-level metals, especially when regulating at lower operating voltages. For example, the conventional approach of utilizing bang-bang control may generate unacceptable output ripple, and utilizing a thermometric control in conventional manners may involve the spatially uniform distribution of hundreds of control bits, which complicates the layout significantly and may be impractical in many designs.

Some low-loading scenarios may utilize only a few thermometer bits, which can result in sparsely-separated turned-on power gates driving a resistive lower-level local power domain metal layer. This may result in problematic current-resistance (IR) gradients due to ineffective current sharing on lower layers and the via stack resistance to reach low-resistance upper layers. High IR gradients negatively impact hold timing closure, resulting in increased voltage margins. This may necessitate the insertion of holding buffers, which increases circuit area and power consumption.

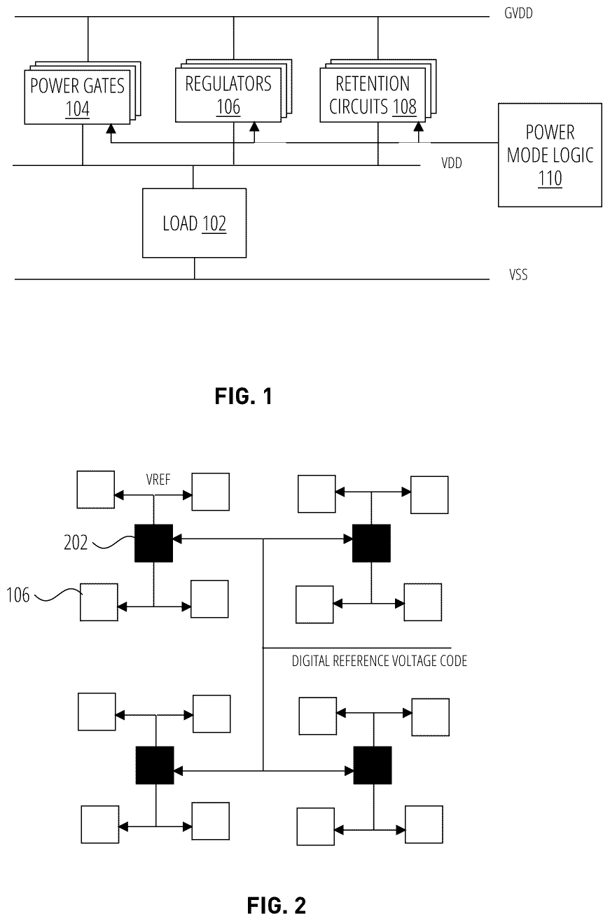

FIG. 1 depicts a power delivery system in one embodiment. The power delivery system is disposed between metal elements providing global power (global power domain GVDD) and metal elements providing power locally (local power domain VDD) to particular a load 102. VSS indicates metal elements implementing the “ground” reference for global and local supply voltage levels.

Depending on the power mode at which to operate the load 102, the power mode logic 110 may activate one of, or combinations of, the power gates 104, regulators 106, and retention circuits 108, in manner described in more detail below.

FIG. 2 depicts the generation of a reference voltage level to the regulators of the power delivery system in one embodiment. A digital reference voltage code is provided to a distributed network of digital-to-analog converters 202, and transformed thereby into the reference voltage level. The reference voltage level is distributed to the regulators 106 of the power delivery system.

The regulators 106 may be distributed on the die of the integrated circuit at a substantially finer than conventional pitch in both the X and Y dimensions. For example, their low area consumption may enable the regulators 106 to be distributed at a pitch of ˜100 um vs ˜800 um in conventional power delivery systems.

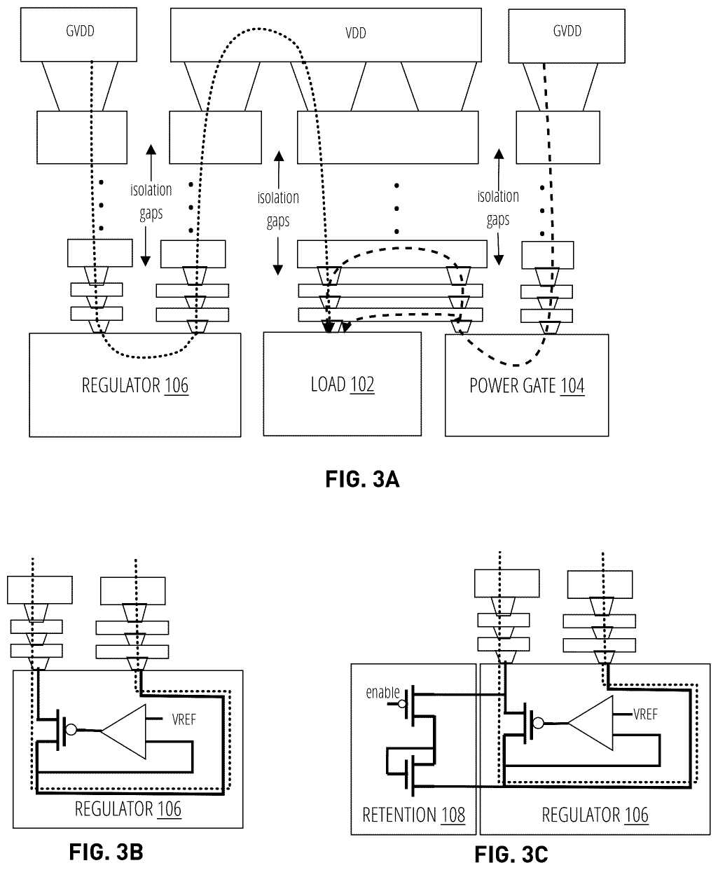

FIG. 3A depicts an embodiment of a power delivery system in other aspects. At a given time during operation, current takes one of the two depicted paths (dotted line or dashed line). In regulation mode, current (dotted line) is drawn by the load 102 from the global power domain through progressively thinner metal layers of an integrated circuit chip/die, or package, through the regulators 106, back through the metal layers to the local power domain, and back down to the load 102 through the metal layers. In a higher performance mode in which lower IR drop is needed, current (dashed line) is also drawn by the load 102 from the global power domain through the metal layers and through the power gates 104, and through the metal layers closer to the load 102.

Herein, “upper metal layers” are those layers closer to the local power domain and global power domain supply layers. “Lower metal layers” are those closer to the load, e.g., logic cells of an integrated circuit. “Progressively thinner” means exhibiting an overall tendency toward thinner metal closer to the integrated circuit. “Progressively thinner” does not require a strict linear progression from thicker to thinner layers.

In P0 mode, all or substantially all of the power gates 104 may be activated (ON) to pass current to the load 102 (e.g., processor core).

Conventionally, implementing voltage regulation via power gating on lower metal layers incurs complications such as uneven IR drop to different components of the load 102 (e.g., due to the higher resistivity of thinner, lower metal layers, resulting in less effective current sharing) and impact on timing margins in different areas of the load 102.

Implementations in accordance with the power delivery system depicted in FIG. 3A ameliorate these challenges by coupling voltage regulator output to upper/thicker metals of the local power domain (VDD) to enable effective current sharing and minimize IR gradients. The regulated local power domain supply voltage is then applied back down through the metal layers to the load 102. This mechanism may provide a more consistent IR drop between the local power domain and the components of the load than do conventional voltage regulation approaches that utilize power gating in regulation power modes. In the various voltage regulated modes P1→Pn, the power gates 104 coupling the global power domain to the local power domain may be de-activated (OFF). FIG. 3B depicts a simplified operating configuration of the regulators 106 in P1→Pn modes, where VREF is set to the nominal VDD supply voltage for the particular power mode.

In retention power mode(s), both of the regulators 106 and the power gates may be de-activated, and the dropout between the global power domain voltage and the local power domain voltage may be controlled by the retention circuits 108. The retention circuits 108 may in one embodiment comprise diode stacks of different lengths configured in parallel with one another and with the voltage regulator(s). In a particular retention mode, the diode stack of the retention circuits 108 providing the needed dropout may be activated. FIG. 3C depicts a simplified operating configuration of the regulators 106 and retention circuits 108 in retention modes (e.g., C1).

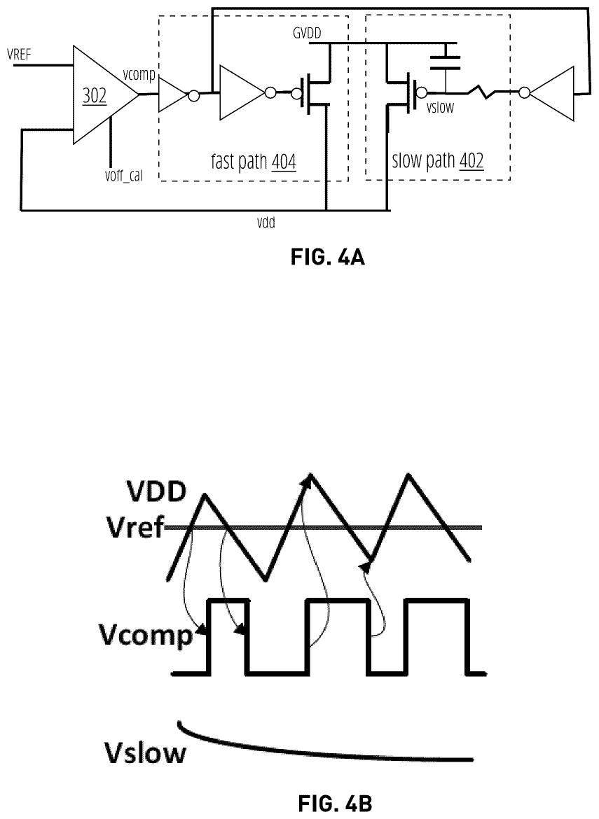

FIG. 4A depicts a voltage regulator in accordance with one embodiment. The depicted regulator circuit may be implemented in low-area on an integrated circuit die, for example is a cell of dimensions 20 um×20 um, making it suitable for distribution across the die, as depicted for example in FIG. 2.

FIG. 4B depicts example signal behavior for the voltage regulator depicted in FIG. 4A. The slow path 402 of the regulator maintains a steady-state amount of current to VDD for operating the load 102. Small variations in the local power domain voltage VDD above and below the desired reference voltage level VREF generate pulses of different widths in the comparator output voltage vcomp which in turn add or subtract current contribution from the global power domain GVDD to VDD using the fast path 404 of the regulator. In some embodiments, the fast path may provide up to 20% of load current to limit and correct undershoot of VREF in response to rapid increases in load demand.

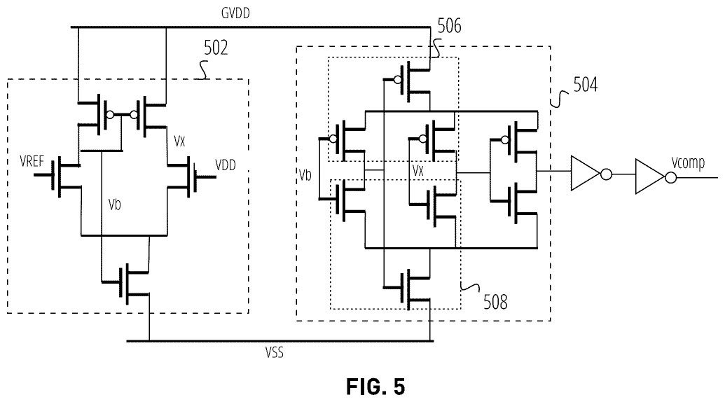

FIG. 5 depicts a complementary self-biased differential comparator circuit in accordance with one embodiment. The depicted circuit or an operationally-similar structure may be utilized as the comparator 302 depicted in the embodiment of FIG. 4A. The comparator generates an output vcomp indicative of the relationship between two input voltages, VREF and VDD. The comparator comprises a pre-amplifier 502 that converts VREF and VDD into voltages Vb and Vx in an output amplifier 504 comprising a complementary PMOS differential amplifier 506 and an NMOS amplifier 508.

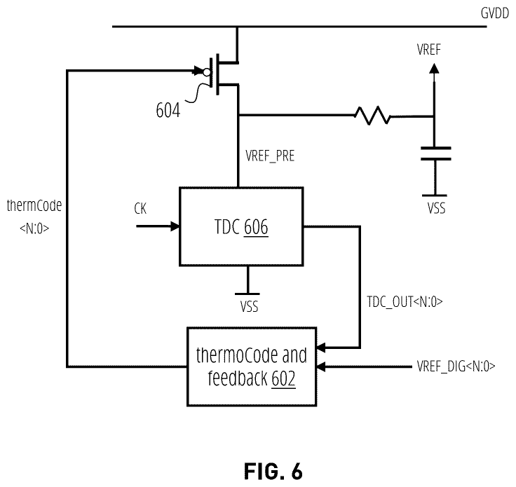

FIG. 6 depicts an embodiment of a reference voltage generator at a high level. The reference voltage generators operates solely from the global power domain supply; an additional/separate power source or domain is not utilized. A digital code VREF_DIG (which may in some embodiments be changed according to a power mode to set) is transformed by thermometer code logic 602 into a thermometer code that is applied to a header circuit 604. The thermometer code determines an amount of current passed by the header circuit 604, which in turn determines an (unfiltered) analog reference voltage level VREF_PRE. The voltage VREF_PRE is filtered (e.g., to remove high-frequency components) into the output reference voltage level VREF.

A time-to-digital converter 606 transforms a fixed-period clock signal CK and the voltage VREF_PRE into a digital code TDC_OUT that is applied, along with the digital code VREF_DIG, to the thermometer code logic 602, which generates adjustments to the thermometer code to maintain VREF at the set point defined by VREF_DIG.

Embodiments in accordance with the depicted mechanism may exhibit lower latency and greater robustness (e.g., tolerance for metastable bits in thermometer codes such as TDC_OUT) over conventional mechanisms.

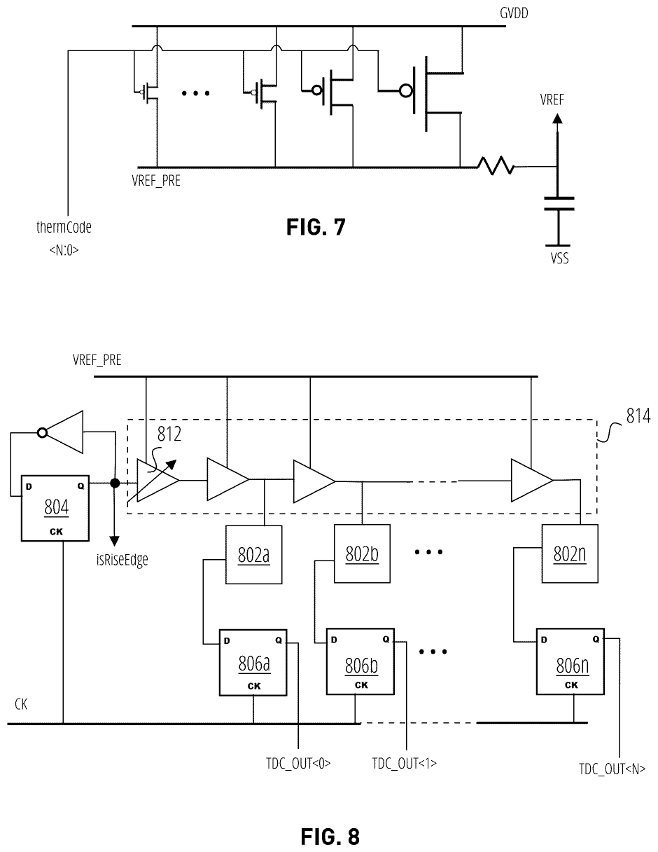

FIG. 7 depicts a header circuit 604 for a reference voltage generator in accordance with one embodiment. The header circuit 604 comprises a number N+1 of pass transistors (e.g., PFETs) arranged in parallel between the global power domain supply and the VREF_PRE node. The pass transistors are configured with progressively stronger strengths (from left to right in the example depiction), wherein a stronger device is configured to pass more current without entering saturation than is a weaker device. The utilization of progressively stronger pass transistors enables a linear relationship between the thermometer codes and VREF. Pass transistor current versus voltage characteristics are non-linear and the progressively stronger arrangement of the pass transistors may effectively cancel these non-linearities resulting in a thermometer code/VREF profile.

FIG. 8 depicts a time-to-digital converter 606 in accordance with one embodiment. A fixed-period input clock signal CK is applied to a flip-flop 804 with negative feedback to generate a sequence of alternating ones and zeros at the input of a delay chain 814. The delay chain comprises a series arrangements of delay circuits 812. The delay chain 814 may be tapped at any stage, thereby providing an adjustable delay. The voltage VREF_PRE is utilized as the upper power supply voltage of the delay chain 814 elements and therefore affects both of the propagation delay and output voltages of the delay chain stages. The output voltages from stages of the delay chain 814 are passed through level shifters 802a, 802b, . . . 802n and clocked to the outputs of a series of corresponding flip-flops 806a, 806b, . . . 806n, where they form the reference digital value TDC_OUT<N:0> that is compared by the thermometer code logic 602 with the digital code for the desired reference voltage level VREF.

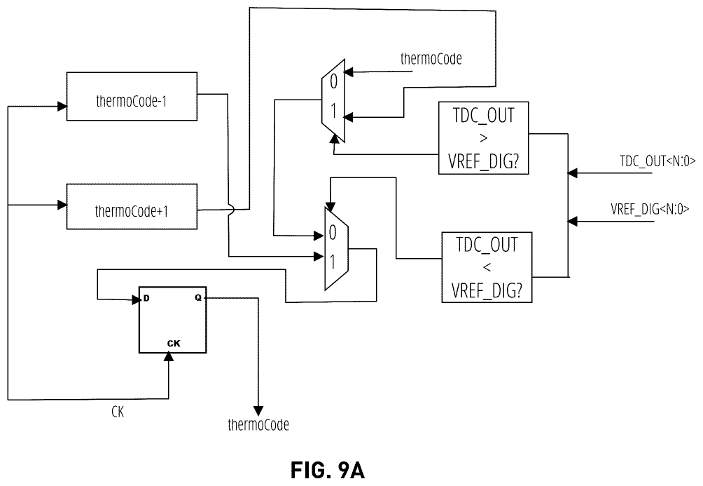

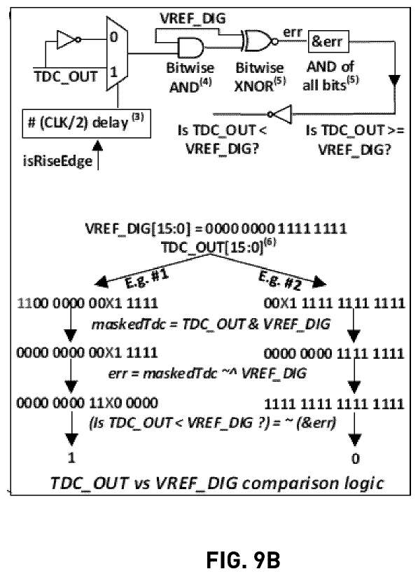

FIG. 9A and FIG. 9B depict thermometer code logic 602 in accordance with one embodiment. Although not depicted for the sake of simplicity, separate rise and fall VREF_DIG codes may be utilized for generation of the thermometer code, where VREF_DIG is a digital encoding for the desired VREF value. For example, on odd-numbered cycles where signal isRiseEdge=1, VREF_DIG may be set to 0000000011111111111111 (odd cycles, isRiseEdge=1). On even-numbered cycles where signal isRiseEdge=0, VREF_DIG may be set to 1111111110000000000000. Utilizing separate rise and fall codes accounts for the operating characteristic of the time-to-digital converter 606, which flips the polarity of the its output (TDC_OUT) every alternate clock cycle due to the toggle flop disposed at the input of the delay chain 814.

Those of skill in the art will appreciate that the depicted logic operations may be carried out in any number of manners. For example, the comparison “TDC_OUT>VREF_DIG” is logically equivalent to evaluating “TDC_OUT>={VREF_DIG[N−1:0], 1′b1}”; the computation ‘thermoCode−1’ is logically equivalent to ‘{1′b0, thermoCode[N:1]}; the computation ‘thermoCode+1’ is logically equivalent to ‘{thermoCode[N−1:0], 1′b1}; and so on.

In FIG. 9B, an ‘X’ in the bits of TDC_OUT denotes a potentially metastable bit. As depicted in FIG. 9B (3), a half clock cycle delay may be applied to align the phase of the isRisingEdge signal (indicating a rising or falling edge) with the corresponding TDC_OUT code. As depicted at FIG. 9B (4), a bitwise AND may be applied to mask out TDC_OUT bits that are not utilized. As depicted at FIG. 9B (5), a bitwise XNOR followed by an AND of all bits of TDC_OUT may be applied to determine whether or not TDC_OUT has reached the number of bits in the VREF_DIG code. As depicted at FIG. 9B (6), the most significant bits of TDC_OUT may potentially comprise residual 1 s from a previous sampling cycle. The logic to set the thermometer code may thereby be made tolerant of metastable bit behavior, due to the metastable bit in TDC_OUT regularly being masked out in the final calculation of thermometer code until the desired VREF level is obtained.

### LISTING OF DRAWING ELEMENTS

102 load
104 power gate
106 regulator
108 retention circuit
110 power mode logic
202 digital-to-analog converter
302 comparator
402 slow path
404 fast path
502 pre-amplifier
504 amplifier
506 PMOS differential amplifier
508 NMOS amplifier
602 thermometer code logic
604 header circuit
606 time-to-digital converter
802a level shifter
802b level shifter
802n level shifter
804 flip-flop
806a flip-flop
806b flip-flop
806n flip-flop
812 delay circuit
814 delay chain

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112 (f) for that claim element. Accordingly, claims in this application that do not otherwise include the “means for” [performing a function] construct should not be interpreted under 35 U.S.C. § 112 (f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended invention as claimed. The scope of inventive subject matter is not limited to the depicted embodiments but is rather set forth in the following Claims.

What is claimed is:

1. A reference voltage generator comprising:
a header circuit configured to pass current from a power supply to a time-to-digital converter, an amount of the current to pass determined by a thermometer code; and
logic to update the thermometer code based on a comparison between an output of the time-to-digital converter and a digital code representing a reference voltage level.

2. The reference voltage generator of claim 1, further comprising:
an arrangement of progressively stronger pass transistors configured to set a linear relationship between the thermometer code and the reference voltage level.

3. The reference voltage generator of claim 1, wherein the logic to update the thermometer code is configured to tolerate metastability.

4. The reference voltage generator of claim 1, further configured to:
apply the current to a delay chain of the time-to-digital converter.

5. The reference voltage generator of claim 1, further configured to:
generate an output reference voltage level; and
the time-to-digital converter configured to generate a sample of the output reference voltage level from the current and a clock signal.

6. The reference voltage generator of claim 5, wherein the logic to generate the thermometer code comprises:
logic to compare the sample of the output reference voltage level to the digital code representing the reference voltage level.

7. The reference voltage generator of claim 6, further comprising:
logic to select one of an increment to the thermometer code or a decrement to the thermometer code based on comparison of the sample of the output reference voltage level to the digital code representing the reference voltage level.

8. The reference voltage generator of claim 1, further comprising:
a low-pass filter configured at a node between the header circuit and the time-to-digital converter.

9. A power delivery system comprising:
a global power domain supply;
a local power domain supply;
a first metal path traversing first metal layers from the global power domain supply to a voltage regulator;
a second metal path traversing second metal layers from the local power domain supply to the voltage regulator;
a third metal path traversing third metal layers from the local power domain supply to an integrated circuit;
electrical isolation gaps formed between the first metal layers, the second metal layers, and the third metal layers;
the voltage regulator configured to receive a reference voltage level from a reference voltage generator comprising:
a header circuit configured to pass current from the global power domain supply to a time-to-digital converter, an amount of the current to pass determined by a thermometer code; and
logic to update the thermometer code based on a comparison between an output of the time-to-digital converter and a digital code representing the reference voltage level.

10. An integrated circuit power delivery network comprising:
a plurality of voltage regulators arranged in the integrated circuit in a grid layout;
a plurality of reference voltage generators interspersed among the voltage regulators, each reference voltage generator configured to provide a reference voltage level to multiple ones of the plurality of voltage regulators;
a first metal path traversing first metal layers from a global power supply to the voltage regulators;
a second metal path traversing second metal layers from a local power supply to the voltage regulators;
a third metal path traversing third metal layers from the local power supply to logic cells of the integrated circuit;
electrical isolation gaps formed between the first metal layers, the second metal layers, and the third metal layers;
a header circuit configured to pass current from the global power supply to a time-to-digital converter, an amount of the current to pass determined by a thermometer code; and
logic to update the thermometer code based on a comparison between an output of the time-to-digital converter and a digital code representing a reference voltage level to apply to the reference voltage generators.

11. The power delivery network of claim 10, wherein the reference voltage generators are powered solely from the global power supply.

12. The power delivery network of claim 10, the voltage regulators configured to electrically couple a lowest layer of first metal layers to a lowest layer of the second metal layers.

13. The power delivery network of claim 10, wherein each of the first metal layers, the second metal layers, and the third metal layers comprise progressively thinner metal layers.

14. The power delivery network of claim 10, further comprising:
a fourth metal path traversing fourth metal layers from the global power domain supply to a plurality of power gates.

15. The power delivery network of claim 14, the power gates configured to electrically couple the fourth metal layers to the third metal layers.

16. The power delivery network of claim 15, the power gates configured to electrically couple a lowest metal layer of the fourth metal layers to a lowest metal layer of the third metal layers.

17. The power delivery network of claim 14, further comprising electrical isolation gaps formed between the fourth metal layers and the first metal layers, the second metal layers, and the third metal layers.

18. The power delivery network of claim 10, further comprising:
a plurality of retention circuits coupled between the first metal layers and the second metal layers.

19. The power delivery network of claim 18, wherein the retention circuits are coupled in parallel with the voltage regulators.

20. The power delivery network of claim 19, wherein the retention circuits each comprise a plurality of diode stacks arranged in parallel.

21. The power delivery network of claim 10, wherein the regulators each comprise a complementary self-biased differential comparator.

22. A system configured to operate an integrated circuit in a plurality of power modes, the system comprising:
a circuit die comprising a plurality of logic cells, a plurality of voltage regulators, a plurality of power gates, and a plurality of retention circuits;
a power delivery network comprising:
a first metal path traversing first metal layers from a global power supply to the voltage regulators and the retention circuits;
a second metal path traversing second metal layers from a local power supply to the voltage regulators and the retention circuits;
a third metal path traversing third metal layers from the local power supply to the logic cells of the integrated circuit;
a fourth metal path traversing fourth metal layers from the global power supply to the power gates;
electrical isolation gaps formed between the first metal layers, the second metal layers, the third metal layers, and the fourth metal layers; and
wherein the voltage regulators each comprise:
a time-to-digital converter;
a header circuit configured to pass current from the global power supply to the time-to-digital converter, an amount of the current to pass determined by a thermometer code; and
logic to update the thermometer code based on a comparison between an output of the time-to-digital converter and a digital code representing a reference voltage level to apply to the reference voltage generators.
